(19) United States
(12) Patent Application Publication
(10) Pub. No.: US 2007/0164383 A1
(43) Pub. Date: Jul. 19, 2007

(54) Magnetic random access memory with improved writing margin

(76) Inventors: Wei-Chuan Chen, Hsinchu (TW); Yung-Hung Wang, Hsinchu (TW); Shan-Yi Yang, Hsinchu (TW); Kuei-Hung Shen, Hsinchu (TW)

Correspondence Address: HARNESS, DICKEY & PIERCE, P.L.C., P.O. BOX 8910, RESTON, VA, 20195, US

(21) Appl. No.: 11/496,405

(22) Filed: Aug. 1, 2006

(30) Foreign Application Priority Data
Jan. 4, 2006 (TW) 095100380

(51) Int. Cl. H01L 29/82

(52) U.S. Cl. 257/427

(57) ABSTRACT

A magnetic memory with improved writing margin is provided, which includes a magnetic tunnel junction device and an adjustment layer. The magnetic tunnel junction device includes an anti-ferromagnetic layer, a pinned layer, a tunnel barrier layer, and a free layer formed sequentially. The adjustment layer is formed on one side of the magnetic tunnel junction device and contacts the free layer. The thickness of the adjustment layer is smaller than 20 nm and it employs Ru or Ru-base materials. The magnetic memory with improved writing margin may improve the switching uniformity and reduce the switching field of the free layer. Therefore, the current necessary for the write word line is reduced.

### CROSS-REFERENCE TO RELATED APPLICATIONS

This non-provisional application claims priority under 35 U.S.C. §119(a) on Patent Application No(s). 095100380 filed in Taiwan, R.O.C. on Jan. 4, 2006 , the entire contents of which are hereby incorporated by reference.

### BACKGROUND OF THE INVENTION

1. Field of Invention

The present invention relates to a magnetic memory, and more particularly to a magnetic memory with an adjustment layer, thus the writing margin thereof is improved.

2. Related Art

Magnetic memory mainly utilizes the characteristic of electron spin to record signals “0” and “1” through the magnetic resistance features generated by different magnetization directions of the free layer of the magnetic structure. Magnetic memory is a non-volatile memory simultaneously having the non-volatile characteristic of flash memory, the high density potential of dynamic random access memory (DRAM), and the quick access advantage of static random access memory (SRAM). When data are written into magnetic memory, a general method is to use two current lines, i.e., bit line and write word line, to induce cells intersected by magnetic fields and change the resistance values of the cells by changing the magnetization directions of the free layer. When magnetic random access memory (MRAM) reads memory data, current sources must be provided to flow into the selected magnetic memory cells, thus reading different resistance values of the cells to determine the digital values of the data.

However, when magnetic memory is developed toward high density, the dimension of the magnetic memory cells must be reduced, such that the switching field of the free layer is enlarged. Thus, the required current increases, which is a great challenge in circuit design. In addition to reducing the current, the other task for magnetic memory design is to make the switching of the free layer of all magnetic memory cells uniform, which is an urgent technical problem to be solved and is the most important problem affecting the production of magnetic memory. At present, most methods directed to solve the problem involve selecting the best shape of the magnetic memory cell or using the writing mechanism. Recently, in order to solve the problem, as for the material of the free layer, CoFeB of a high magnetic resistance change rate can be replaced by the magnetic material NiFe of low magnetostriction coefficient, to solve the problem of the switching uniformity of the free layer. However, the high magnetic resistance change rate is given up, which is a big disadvantage of this device design.

Referring to FIG. 1, it is an architecture view of the magnetic memory provided by the prior art. The magnetic memory disclosed in U.S. Pat. No. 6,744,608 is shown in FIG. 1 for convenience of illustration and comparison. It mainly comprises an anti-ferromagnetic layer 110, a pinned layer 120 formed on the anti-ferromagnetic layer 110, a tunnel barrier layer 130 formed on the pinned layer 120, a free layer 140 formed on the tunnel barrier layer 130, a covering layer 150 formed on the free layer 140, and a mask layer 160 formed on the covering layer 150. A metal wire 100 is disposed beneath the anti-ferromagnetic layer 110. The material of the covering layer 150 includes Ta or TaN, while the material of the mask layer 160 includes Ta, Ti, Cr, or TaN. The covering layer 150 made of Ta or TaN is mainly used to protect the free layer 140 in the device from being oxidized and damaged when etching. The patent mainly discloses a fabricating method capable of controlling the size of the device without suggesting or instructing using the covering layer 150 to improve the switching field of the free layer.

### SUMMARY OF THE INVENTION

In view of the technical problem existing in the prior art, the present invention discloses a magnetic memory with improved writing margin, to solve the problem of the uniformity of the switching field of the free layer.

The magnetic memory with the improved writing margin disclosed by the invention comprises a magnetic tunnel junction device, which includes an anti-ferromagnetic layer, a pinned layer, a tunnel barrier layer, and a free layer sequentially formed; and an adjustment layer formed on one side of the magnetic tunnel junction device and contacting the free layer.

According to the embodiment of the invention, the thickness of the adjustment layer is smaller than 20 nm.

According to the embodiment of the invention, the material of the adjustment layer is Ru or a Ru-base material.

The magnetic memory with the improved writing margin disclosed by the invention can improve the switching uniformity of the free layer.

The magnetic memory with the improved writing margin disclosed by the invention can reduce the switching field of the free layer, so as to reduce the current required by the write word line.

The above illustration of the content of the invention and the following illustration of the embodiments are intended to demonstrate and explain the spirit and principle of the invention, and provide further explanations for the claims of the invention.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only, and which thus is not limitative of the present invention, and wherein:

FIG. 1 shows the MTJ structure of magnetic access memory disclosed in the prior art;

FIGS. 2A and 2B show the MTJ structure of magnetic access memory disclosed by the invention;

FIG. 3 shows the magnetic resistance change (R-H loop) of the magnetic access memory with the structure disclosed in the prior art;

FIG. 4 shows the astroid curves of the magnetic access memory with the structure disclosed in the prior art;

FIG. 5 shows the magnetic resistance change (R-H loop) of the magnetic access memory with the structure disclosed by the invention;

FIG. 6 shows the astroid curves of the magnetic access memory with the structure disclosed by the invention; and

FIGS. 7 to 13 show the fabricating flow of the magnetic access memory with the structure disclosed by the invention.

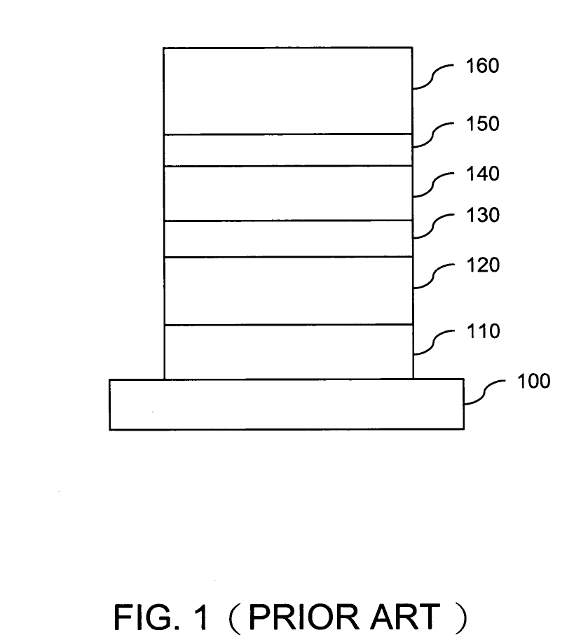

### DETAILED DESCRIPTION OF THE INVENTION

The detailed features and advantages of the invention are discussed in detail in the following embodiments. Anybody skilled in the related arts can easily understand and implement the content of the technology of the invention. Furthermore, the relative objects and advantages of the invention are apparent to those skilled in the related arts according to the content disclosed in the specification, claims, and drawings.

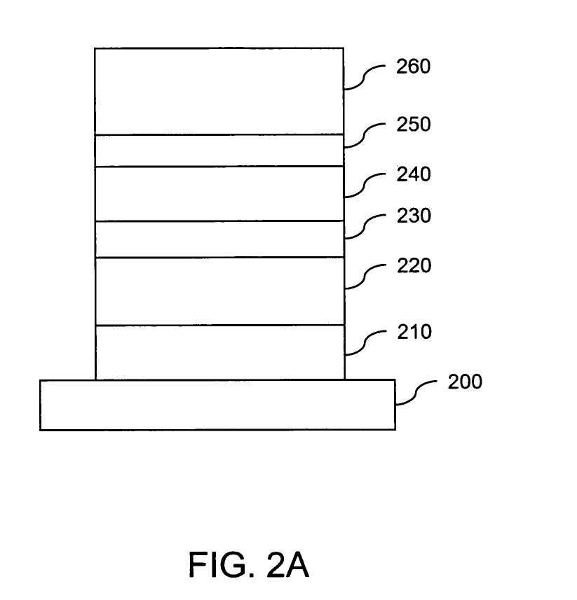

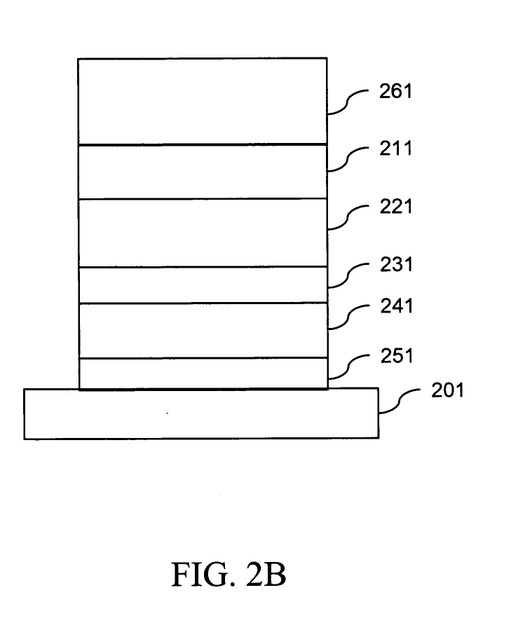

Referring to FIG. 2A, it shows the simplified sectional view of a general MTJ of the invention. In FIG. 2A, only one MTJ is shown. In fact, a RAM array comprises many RAMs in FIG. 2A.

The magnetic memory cell in the MRAM disclosed by the invention comprises an anti-ferromagnetic layer 210, a pinned layer 220 formed on the anti-ferromagnetic layer 210, a tunnel barrier layer 230 formed on the pinned layer 220, a free layer 240 formed on the tunnel barrier layer 230, an adjustment layer 250 formed on the free layer 240, and a mask layer 260 formed on the adjustment layer 250. A first metal wire 200 is formed beneath the anti-ferromagnetic layer 210. When the device is finished, a second metal wire (not shown) is formed above the adjustment layer 250, which will be illustrated in detail in the fabricating flow.

The anti-ferromagnetic layer 210, the pinned layer 220 formed on the anti-ferromagnetic layer 210, the tunnel barrier layer 230 formed on the pinned layer 220, and the free layer 240 formed on the tunnel barrier layer 230 constitute a magnetic tunnel junction device.

The anti-ferromagnetic layer 210 is made of an anti-ferromagnetic material, for example, PtMn or IrMn.

In an embodiment, the pinned layer 220 formed on the anti-ferromagnetic layer 210 adopts more than one ferromagnetic layer. In another embodiment, it adopts an artificial anti-ferromagnetic layer of a three-layer structure. The artificial anti-ferromagnetic layer of a three-layer structure can be formed by sequentially stacking a ferromagnetic material, a non-magnetic metal, and a ferromagnetic material, wherein the magnetization directions of the two ferromagnetic layers are arranged in anti-parallel. For example, a three-layer structure of CoFe/Ru/CoFe can be used.

The material of the tunnel barrier layer 230 formed on the pinned layer 220 is, for example, AlOx or MgO.

The free layer 240 formed on the tunnel barrier layer 230 adopts more than one ferromagnetic layer or an artificial anti-ferromagnetic layer of a three-layer structure. The material of the ferromagnetic layer is NiFe/CoFe or CoFeB. The artificial anti-ferromagnetic layer is formed by sequentially stacking a ferromagnetic layer, a magnetic metal layer, and a ferromagnetic layer, for example, NiFe/Ru/NiFe or CoFeB/Ru/CoFeB. Besides ferromagnetic material, other magnetic materials having the same characteristic can also be adopted. The magnetization direction of the free layer 240 can be changed freely.

The adjustment layer 250 is made of metal materials like Ru or Ru-base materials such as alloys, oxides, or nitrides containing Ru, for improving switching uniformity, effectively reducing the switching field, and enlarging the write operating range at the same time. The thickness of the adjustment layer is smaller than 20 nm, and preferably 0.3˜5 nm.

The adjustment layer that is made of a material different from that of the free layer is used to adjust the stress, interface condition, magnetic property, and the like of the free layer so as to obtain an optimal free layer. Generally, if an etching mask directly made of Ta contacts the free layer, the size and uniformity of the switching field of the free layer are both poor. According to the invention, an adjustment layer is added between the free layer and the mask layer to prevent the cross-diffusion between the mask layer and the free layer, and adjust the magnetic property of the free layer at the same time.

Besides the embodiment as shown in FIG. 2A, another embodiment disclosed by the invention is shown in FIG. 2B, which comprises an adjustment layer 251, a free layer 241 formed on the adjustment layer 251, a tunnel barrier layer 231 formed on the free layer 241, a pinned layer 221 formed on the tunnel barrier layer 231, an anti-ferromagnetic layer 211 formed on the pinned layer 221, and a mask layer 261 formed on the anti-ferromagnetic layer 211. A first metal wire 201 is formed beneath the adjustment layer 251. When the device is finished, a second metal wire (not shown) is formed on the mask layer 261.

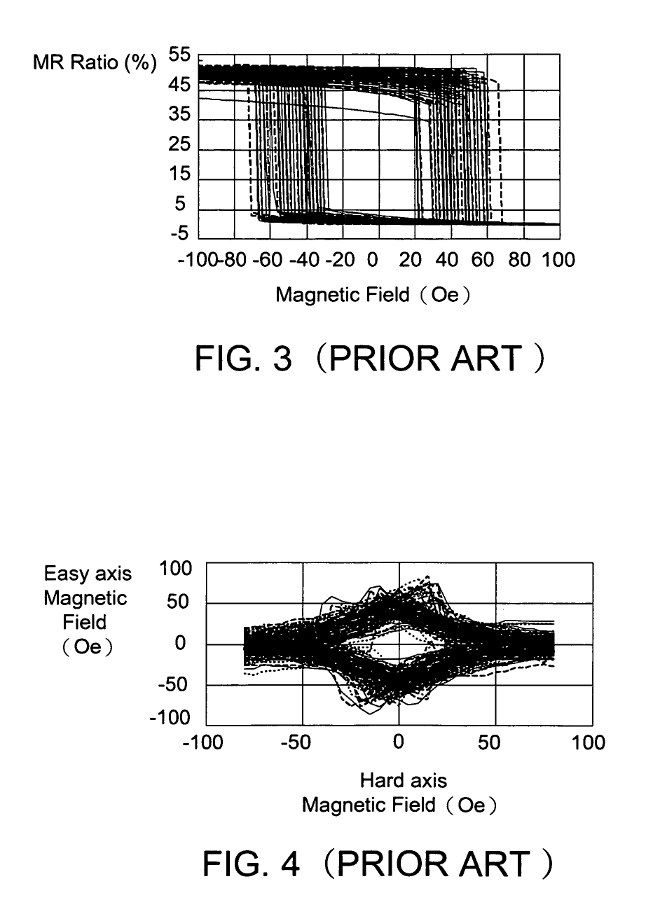

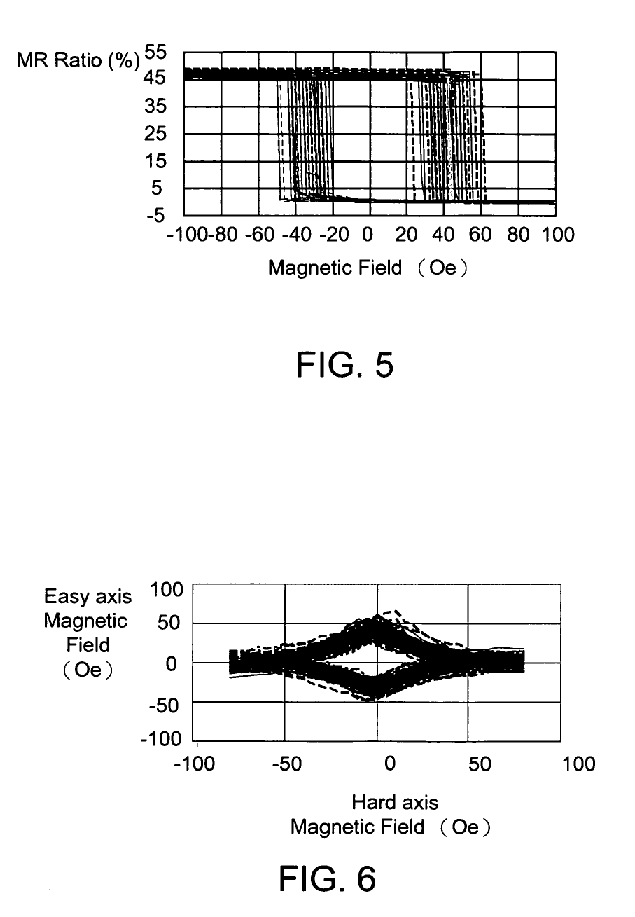

Referring to FIGS. 3 and 4, overlapping graphs of the magnetic resistance changes and write operating ranges of multiple magnetic memories without adjustment layers are shown. Seen from the data in the figures, the switching fields of the free layers of the magnetic memories without adjustment layers are more widely distributed, and the required switching fields are big without any write operating range. Referring to FIGS. 5 and 6, overlapping graphs of the magnetic resistance changes and write operating ranges of multiple magnetic memories with adjustment layers are shown. Seen from the data in the figures, the switching fields of the free layers of the magnetic memories with adjustment layers are more uniform, and the required switching fields are small. As such, an adjustment layer made of Ru or Ru-base materials can improve the switching uniformity and effectively reduce the switching field.

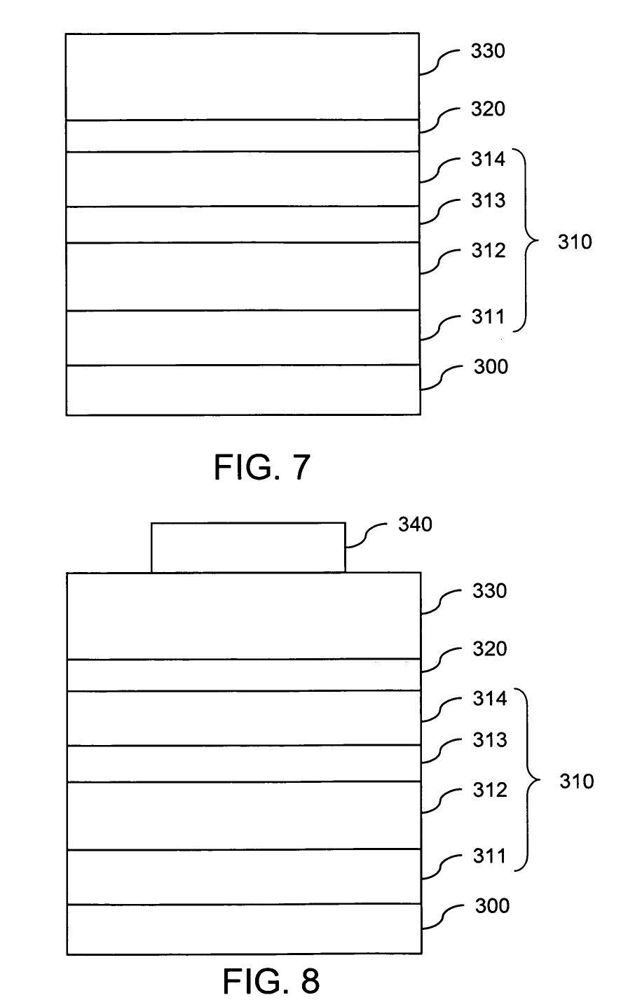

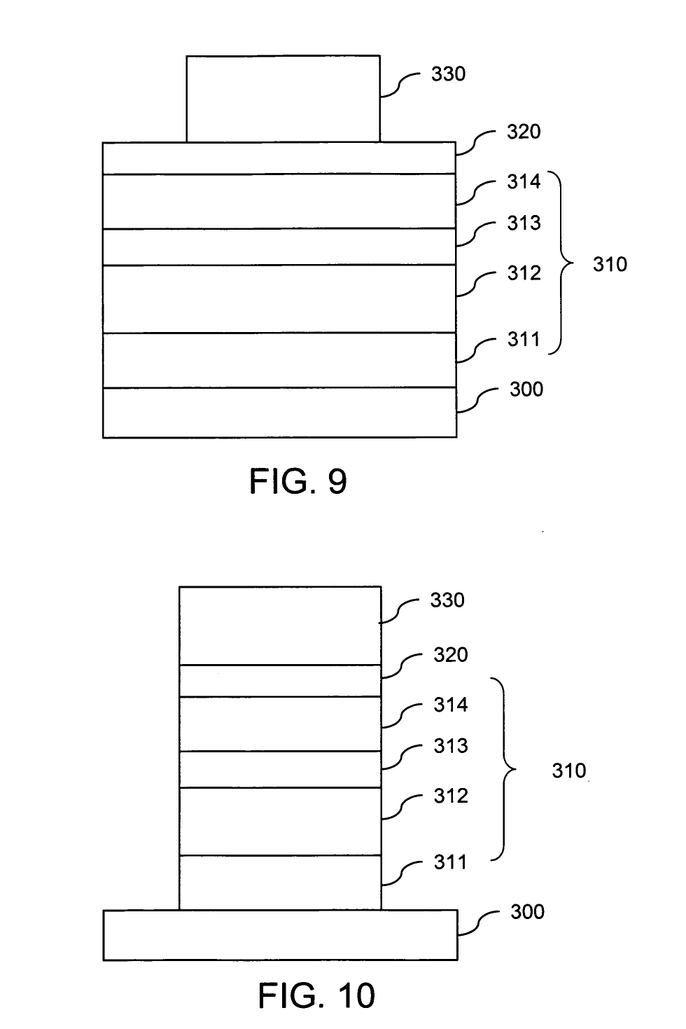

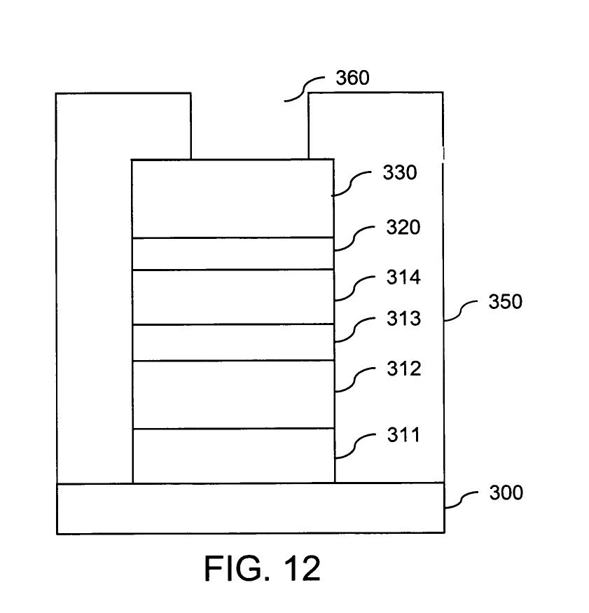

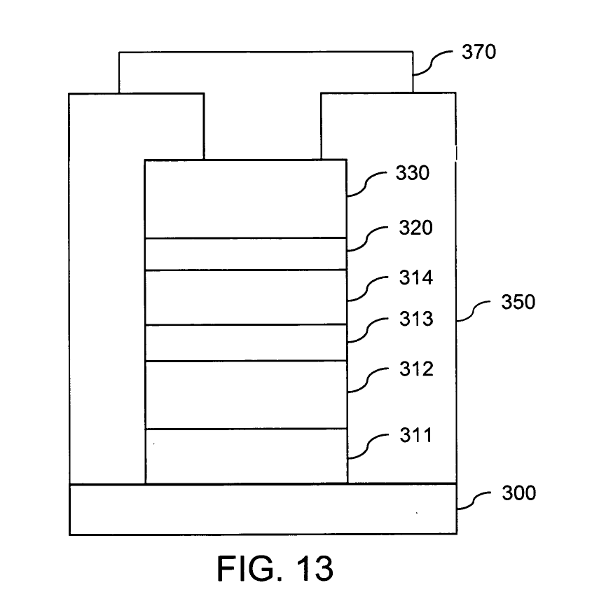

Referring to FIGS. 7 to 13, the method for fabricating the magnetic memory device disclosed by the invention is shown.

As shown in FIG. 7, a first metal wire 300 is formed, and then a magnetic memory cell 310 is deposited by sputtering. The magnetic cell 310 includes an anti-ferromagnetic layer 311, a pinned layer 312, a tunnel barrier layer 313, and a free layer 314 formed sequentially. And an adjustment layer 320 and a mask layer 330 are formed on the magnetic memory cell 310.

Afterward, a photoresist 340 is formed on the mask layer 330. The photoresist 340 corresponds to the shape of the magnetic memory to be formed. Then, the mask layer 330 is etched into the shape corresponding to that of the photoresist 340 and the shape of the magnetic memory cell to be formed. Next, the photoresist 340 is removed. The mask layer 330 is then taken as an etching mask and the magnetic memory cell is etched to complete the fabrication of the memory cell, as shown in FIGS. 7 to 10.

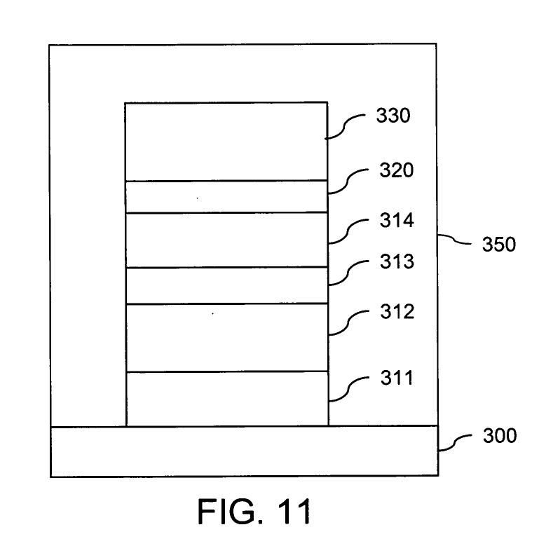

Then, a dielectric layer 350 is formed as a protection layer. A contact window 360 is formed on the dielectric layer 350 approximately corresponding to the memory cell. A second metal wire 370 is filled into the contact window 360 and is etched to be a desired shape, as shown in FIGS. 11 to 13.

The invention adds an adjustment layer between the free layer and the mask layer to improve the switching uniformity of the free layer, and to reduce the switching field and the current required by the write word line, without affecting the magnetoresistance significantly.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A magnetic random access memory (MRAM) with improved writing margin, comprising:
a magnetic tunnel junction device, including an anti-ferromagnetic layer, a pinned layer, a tunnel barrier layer, and a free layer; and
an adjustment layer, formed on one side of the magnetic tunnel junction device and contacting the free layer.

2. The MRAM according to claim 1, wherein the material of the adjustment layer is Ru or a Ru-base material.

3. The MRAM according to claim 2, wherein the Ru-base material is selected from among Ru alloys, Ru oxides, Ru nitrides, and combinations thereof.

4. The MRAM according to claim 1, wherein the pinned layer comprises more than one ferromagnetic layer.

5. The MRAM according to claim 1, wherein the pinned layer comprises an artificial anti-ferromagnetic layer formed by sequentially stacking a ferromagnetic material, a non-magnetic metal, and a ferromagnetic material.

6. The MRAM according to claim 1, wherein the free layer comprises more than one magnetic layer.

7. The MRAM according to claim 1, wherein the free layer comprises an artificial anti-ferromagnetic layer formed by sequentially stacking a magnetic layer, a non-magnetic metal layer, and a magnetic layer.

8. The MRAM according to claim 1, further comprising a mask layer formed on the other side of the adjustment layer.

9. The MRAM according to claim 8, further comprising a first metal wire disposed on the other side of the anti-ferromagnetic layer, and a second metal wire disposed on the other side of the mask layer.

10. The MRAM according to claim 1, wherein the anti-ferromagnetic layer, the pinned layer, the tunnel barrier layer, and the free layer are sequentially formed.

11. The MRAM according to claim 1, wherein the free layer, the tunnel barrier layer, the pinned layer, and the anti-ferromagnetic layer are sequentially formed.

12. A MRAM with improved writing margin, comprising:
a magnetic tunnel junction device, including an anti-ferromagnetic layer, a pinned layer, a tunnel barrier layer, and a free layer; and
an adjustment layer, formed on one side of the magnetic tunnel junction device and contacting the free layer, wherein the thickness of the adjustment layer is smaller than 20 nm.

13. The MRAM according to claim 12, wherein the thickness of the adjustment layer falls in a range of 0.1˜10.0 nm.

14. The MRAM according to claim 12, wherein the material of the adjustment layer is Ru or a Ru-base material.

15. The MRAM according to claim 14, wherein the Ru-base material is selected from among Ru alloys, Ru oxides, Ru nitrides, and combinations thereof.

16. The MRAM according to claim 12, wherein the pinned layer comprises more than one ferromagnetic layer.

17. The MRAM according to claim 12, wherein the pinned layer comprises an artificial anti-ferromagnetic layer formed by sequentially stacking a ferromagnetic material, a non-magnetic metal, and a ferromagnetic material.

18. The MRAM according to claim 12, wherein the free layer comprises more than one magnetic layer.

19. The MRAM according to claim 12, wherein the free layer comprises an artificial anti-ferromagnetic layer formed by sequentially stacking a magnetic layer, a non-magnetic metal layer, and a magnetic layer.

20. The MRAM according to claim 12, wherein the anti-ferromagnetic layer, the pinned layer, the tunnel barrier layer, and the free layer are sequentially formed.

21. The MRAM according to claim 12, wherein the free layer, the tunnel barrier layer, the pinned layer, and the anti-ferromagnetic layer are sequentially formed.
